(19) United States
(12) Patent Application Publication
(10) Pub. No.: US 2023/0421097 A1
(43) Pub. Date: Dec. 28, 2023

(54) Solar Cell Module

(71) Applicant: Meyer Burger (Germany) GmbH, Hohenstein-Ernstthal (DE)

(72) Inventors: Heiko Mehlich, Chemnitz (DE); Rainer Grischke, Sugiez (CH); Simon Hänni, Thun (CH); Marcel König, Chemnitz (DE); Pierre Papet, Hauterive (CH)

(21) Appl. No.: 18/038,128

(22) PCT Filed: Nov. 18, 2021
(86) PCT No.: PCT/EP2021/082205

§ 371 Date: May 22, 2023

(30) Foreign Application Priority Data
Nov. 23, 2020 (DE) 10 2020 130 897.3

(51) Int. Cl. H02S 40/34; H01L 31/05; H01L 31/049; H01L 31/048

(52) U.S. Cl. CPC H02S 40/34; H01L 31/0504; H01L 31/049; H01L 31/0488

(57) ABSTRACT

Solar cell module (2000) with a first solar cell string (2121, . . . , 2124), wherein the first solar cell string (2121, . . . , 2124) has at least two solar cells (2121, . . . , 2124) connected in series and arranged in two rows, with a first bypass element (2151) which is connected in parallel with the first solar cell string (2121, . . . , 2124), with a second solar cell string (2221, . . . , 2224) wherein the second solar cell string (2221, . . . , 2224) has at least two solar cells (2221, . . . , 2224) connected in series and arranged in two rows, with a second bypass element (2251) which is connected in parallel to the second solar cell string (2221, . . . , 2224), with a front side encapsulation layer (2002) and a rear side encapsulation layer (2003), wherein the solar cells (2121, . . . , 2124, 2221, . . . , 2224) of the first solar cell string (2121, . . . , 2124) and the second solar cell string (2221, . . . , 2224) are arranged between the front side encapsulation layer (2002) and the rear side encapsulation layer (2003), with an electrical internal connector (2062) arranged between the front side encapsulation layer (2002) and the rear side encapsulation layer (2003), and
to which the first solar cell string (2121, . . . , 2124) and the second solar cell string (2221, . . . , 2224) are connected in series, wherein the first bypass element (2151) and the second bypass element (2251) are arranged on the side of the rear side encapsulation layer (2003) facing away from the front side encapsulation layer (2002), wherein the first bypass element (2151) and the second bypass element (2251) are electrically conductively connected to each other with an external electrical connector (2072) arranged on the side of the rear side encapsulation layer (2003) facing away from the front side encapsulation layer (2002).

The present invention relates to a solar cell module.

WO 2015/001413 A1 discloses a solar cell module which comprises a plurality of solar cell strings, each solar cell string having a plurality of solar cells connected in series. In this case, the solar cells are arranged between a front side encapsulation layer and a rear side encapsulation layer.

When a solar cell is illuminated with light, it generates a current that is essentially proportional to the light intensity. Due to the series circuit, the solar cell that is least illuminated and thus generates the least current limits the total current of the solar cell module. As a result, if a single solar cell is shaded, the solar cell module hardly delivers any more power. In WO 2015/001413 A1 it is therefore proposed to provide bypass diodes, which are connected in parallel to the solar cell strings, so that the solar cell module still supplies power even when the solar cells are partially shaded.

In particular, it is proposed to provide one common bypass diode for each pair of parallel-connected solar cell strings, which is arranged in a separate junction box.

The proposed arrangement of the bypass diodes requires a large number of feedthroughs through the rear side encapsulation layer, so that the risk of moisture entering between the front side encapsulation layer and the rear side encapsulation layer is increased.

Based on this, the present invention is based on the object of providing a solar cell module in which the solar cells are better protected against harsh environmental conditions.

This object is achieved with the subject matter of the main claim. Advantageous embodiments are specified in the dependent claims.

A solar cell module with a first solar cell string is proposed, wherein the first solar cell string has at least two solar cells connected in series and arranged in two rows, with a first bypass element, which is connected in parallel to the first solar cell string, with a second solar cell string, wherein the second solar cell string has at least two solar cells connected in series and arranged in two rows, with a second bypass element, which is connected in parallel to the second solar cell string, with a front side encapsulation layer and a rear side encapsulation layer, wherein the solar cells of the first solar cell string and the second solar cell string are arranged between the front side encapsulation layer and the rear side encapsulation layer, with an internal electrical connector, which is arranged between the front side encapsulation layer and the rear side encapsulation layer, and with which the first solar cell string and the second solar cell string are connected in series, wherein the first bypass element and the second bypass element are arranged on the side of the rear side encapsulation layer facing away from the front side encapsulation layer, and wherein the first bypass element and the second bypass element are electrically conductively connected to one another with an external electrical connector arranged on the side of the rear side encapsulation layer facing away from the front side encapsulation layer.

The provision and arrangement of the internal electrical connector and the external electrical connector makes it possible to reduce the number of feedthroughs through the rear side encapsulation layer. In addition, the bypass elements can be provided on the side of the rear side encapsulation layer facing away from the front side encapsulation layer, as a result of which simpler cooling of the bypass elements can be made possible. The external electrical connector can be, for example, a cable. The flexibility that a cable has over a rigid conductor track can further increase the robustness of the solar cell module.

The bypass element can be a bypass diode. In principle, it is also conceivable to provide two parallel-connected bypass diodes as the bypass element, as a result of which the reliability can be increased and/or as a result of which a larger cooling surface can be provided. It is also conceivable that the bypass element is an active switch, which bypasses this solar cell string when the current decreases due to increasing shading of the corresponding solar cell string. This active switch can be implemented, for example, by a field effect transistor (e.g., MOSFET) with integrated control. Compared to bypass diodes, active switches can feature lower losses and a lower voltage drop across the bypass element. Likewise, with active switches, less heat generated may have to be dissipated. This can make it possible to dispense with bulky heat sinks. Active switches can also be implemented with smaller dimensions.

In one configuration, the solar cell module has a junction box arranged on the side of the rear side encapsulation layer facing away from the front side encapsulation layer, wherein the first bypass element and the second bypass element are arranged in the junction box. Providing the first and second bypass elements in a junction box can reduce the cost of manufacturing the solar cell module. In particular, a common heat sink can be provided for the first bypass element and the second bypass element. If the first bypass element and the second bypass element are active switches, the bypass elements may have common electrical elements, for example a voltage supply. It is also conceivable to arrange several bypass elements in a common chip. In a further configuration, the solar cell module has a third solar cell string, wherein the third solar cell string has at least two solar cells connected in series and arranged in two rows. The third solar cell string can be arranged mirror-symmetrically to the first solar cell string. Providing the third solar cell string can allow a larger number of solar cells to be accommodated in an optimized manner given the external dimensions of the solar cell module, so that the total output of the solar cell module can be increased.

In one configuration, the third solar cell string can be connected in parallel to the first solar cell string. The parallel connection of solar cell strings can help to increase the current provided by the solar cell module while the output voltage remains the same.

In another configuration, the third solar cell string is insulated from the first solar cell string between the front side encapsulation layer and the rear side encapsulation layer. The electrical connection to the first solar cell string can be provided, for example, via an external electrical connector. In this case, the external electrical connector is not arranged between the front side encapsulation layer and the rear side encapsulation layer, but outside. There is no electrical connection between the first solar cell string and the third solar cell string within the laminate formed by the front side encapsulation layer and the rear side encapsulation layer.

Furthermore, a further configuration provides that the solar cell module comprises a third bypass element, which is connected in parallel to the third solar cell string. This can further increase the reliability of the solar cell module. Depending on the number of solar cell strings, further bypass elements can also be provided. In particular, the number of bypass elements can correspond to the number of solar cell strings.

In a further configuration, it is provided that the solar cells of the solar cell module are half cells or multi-divided cells. Half cells are characterized by particularly efficient power generation, since ohmic losses can be minimized The use of multi-divided cells can allow larger solar cell wafers to be used efficiently.

In configurations of the solar cell module, a front side glass can be arranged on the side of the front side encapsulation layer facing away from the rear side encapsulation layer. The front side glass can on the one hand protect the solar cell module from environmental influences and on the other hand optimize the coupling of light into the solar cells.

On the side of the rear side encapsulation layer facing away from the front side encapsulation layer, a rear side glass or a backsheet can be arranged, wherein the first bypass element and/or the second bypass element and/or the third bypass element are arranged on the side of the rear side glass or backsheet facing away from the rear side encapsulation layer. The rear side glass or backsheet can further increase the mechanical strength of the solar cell module.

In configurations, the solar cell module is set up to generate electricity both when light passes through the front side encapsulation layer and when light passes through the rear side encapsulation layer. This may allow the solar cell module to be used in a variety of orientations. Corresponding solar cell modules can also be referred to as bifacial solar cell modules.

In another configuration, the first bypass element and/or the second bypass element and/or the third bypass element each comprise a diode.

Exemplary embodiments of the solar cell module provide that the number of feedthroughs through the rear side encapsulation layer is less than the number of bypass elements of the solar cell module. In this case, it is conceivable that the number of feedthroughs through the rear side glass or the backsheet is even lower than the number of feedthroughs through the rear side encapsulation layer.

The above and other examples are explained below by reference to the drawings. In the drawings:

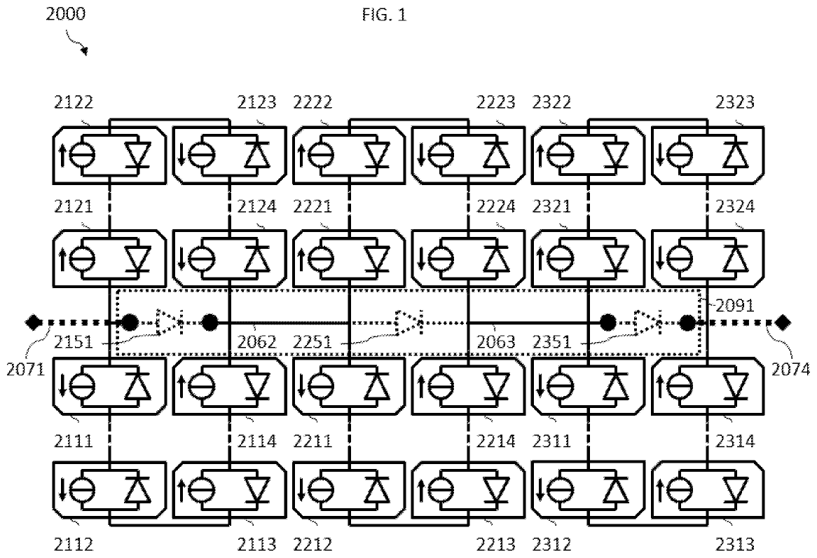

FIG. 1 shows schematically a solar cell module in plan view;

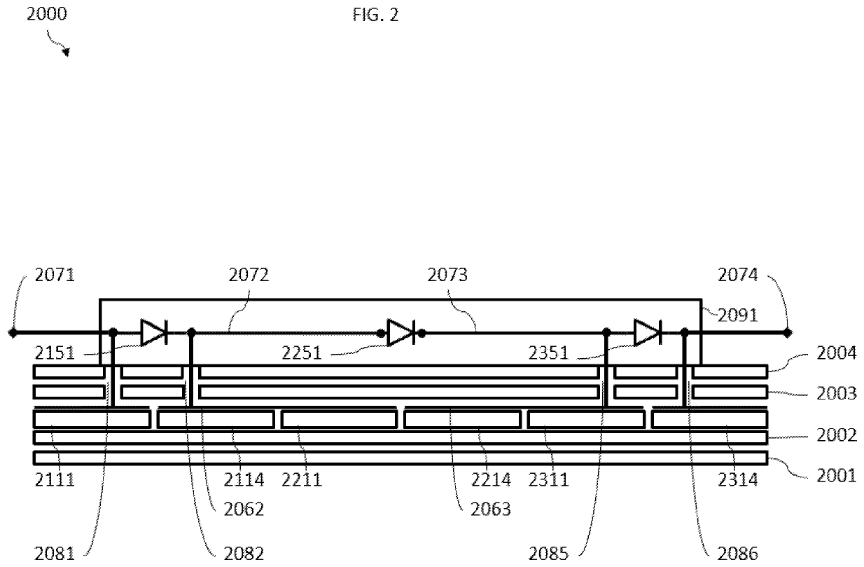

FIG. 2 shows a schematic sectional of the solar cell module shown in FIG. 1;

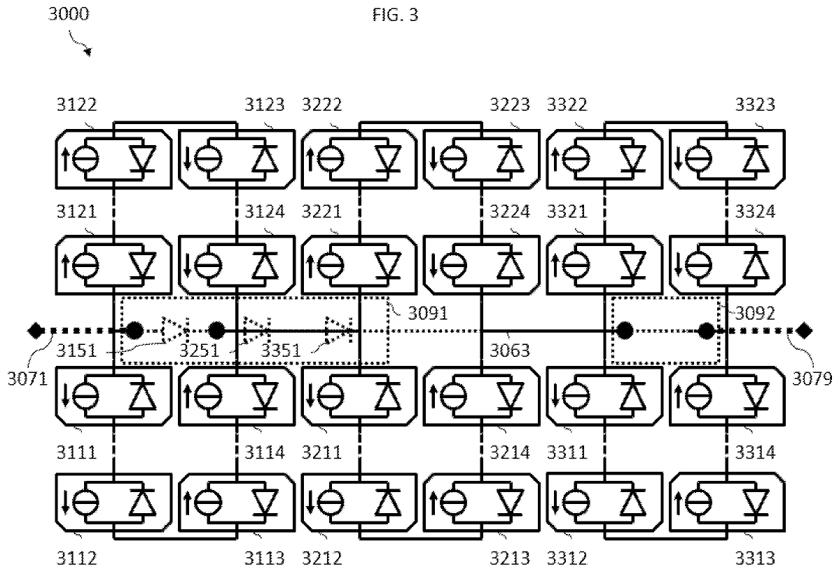

FIG. 3 shows schematically a solar cell module in plan view;

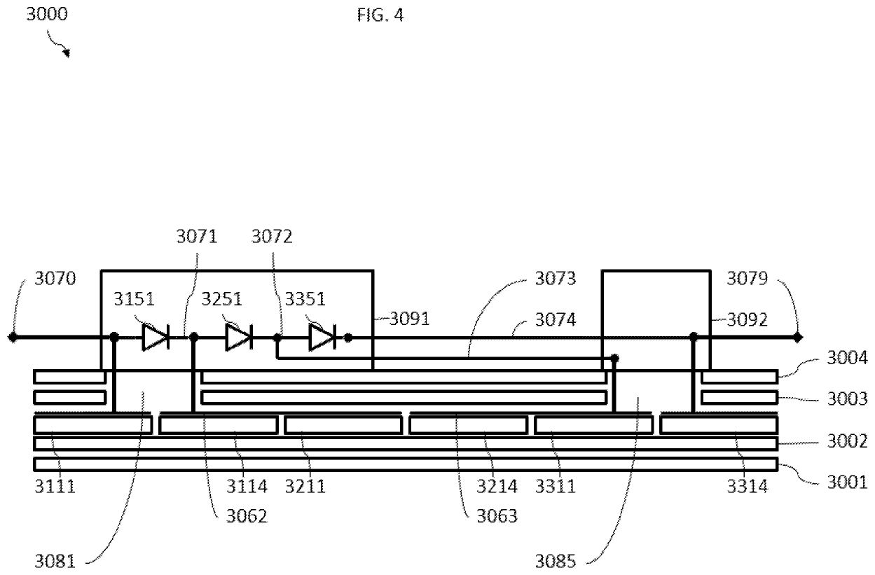

FIG. 4 shows a schematic sectional view of the solar cell module shown in FIG. 3;

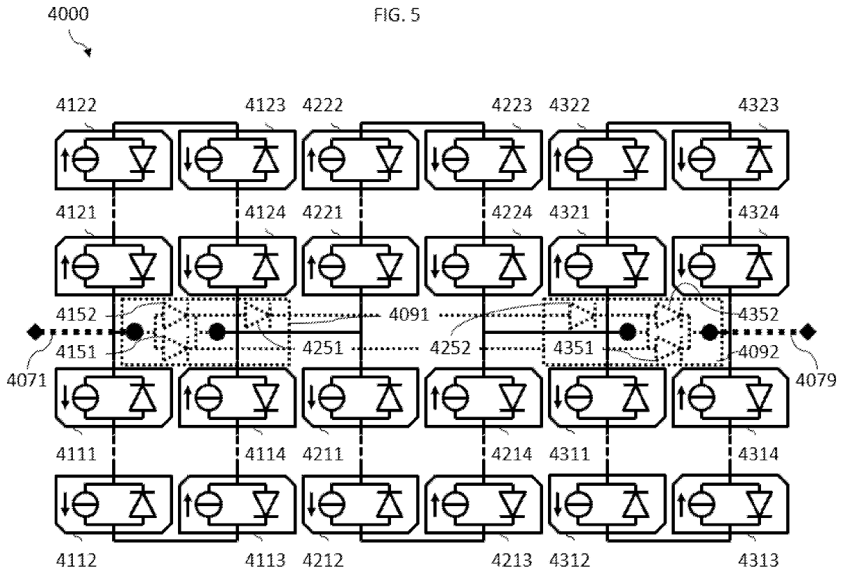

FIG. 5 shows schematically a solar cell module in plan view;

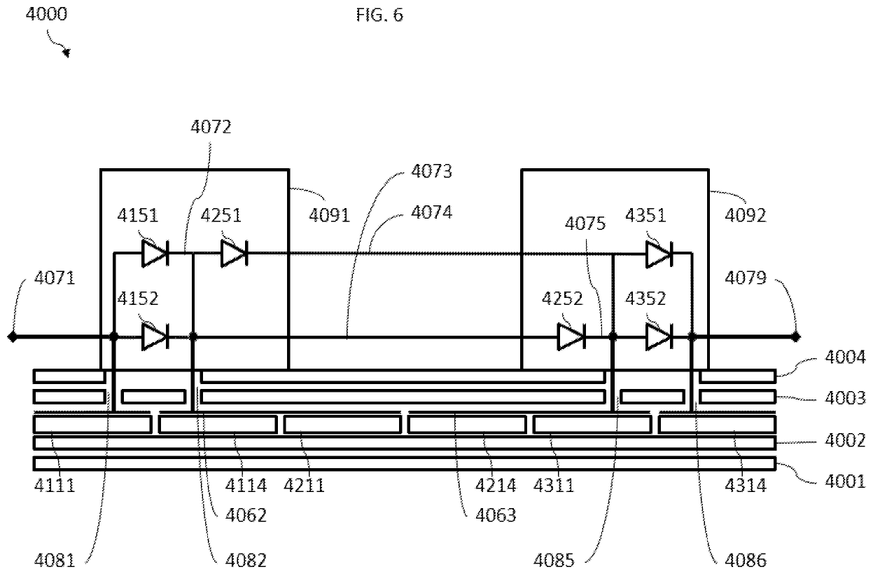

FIG. 6 shows schematically a sectional view of the solar cell module shown in FIG. 5;

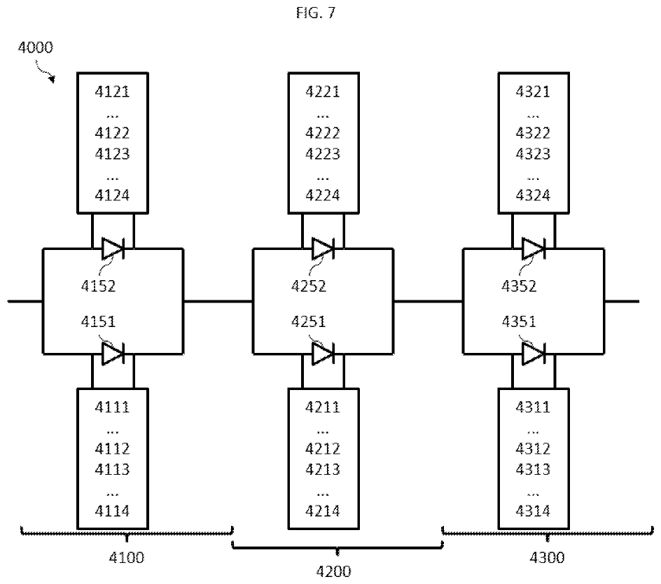

FIG. 7 shows a schematic circuit diagram of the solar cell module shown in FIG. 5;

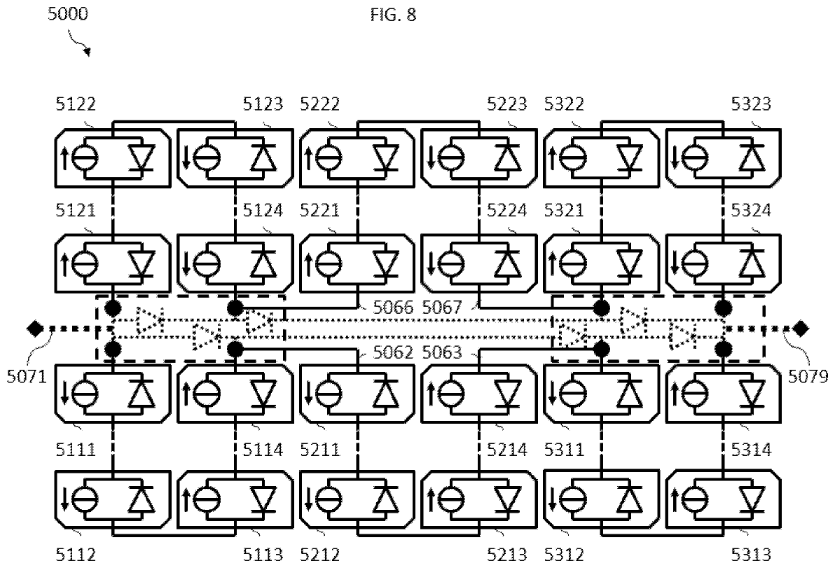

FIG. 8 shows schematically a solar cell module in plan view;

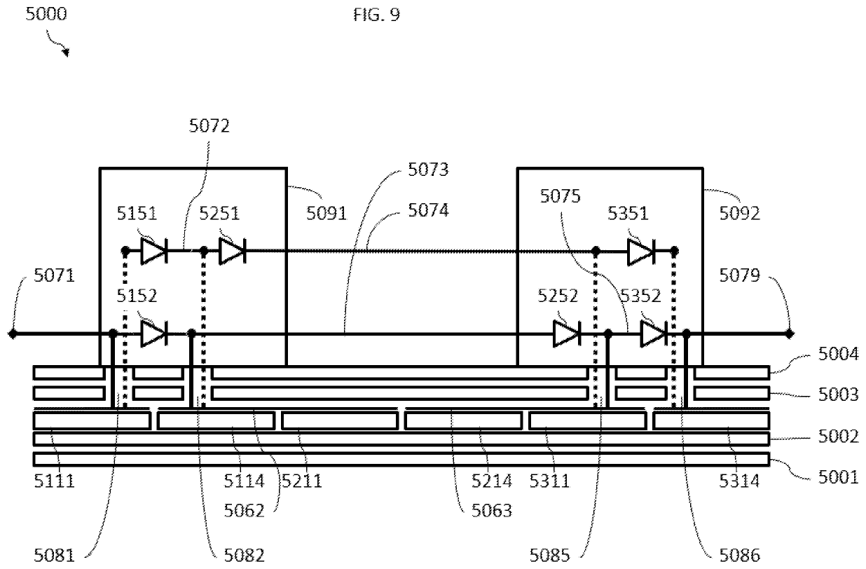

FIG. 9 shows schematically a sectional view of the solar cell module shown in FIG. 8; and

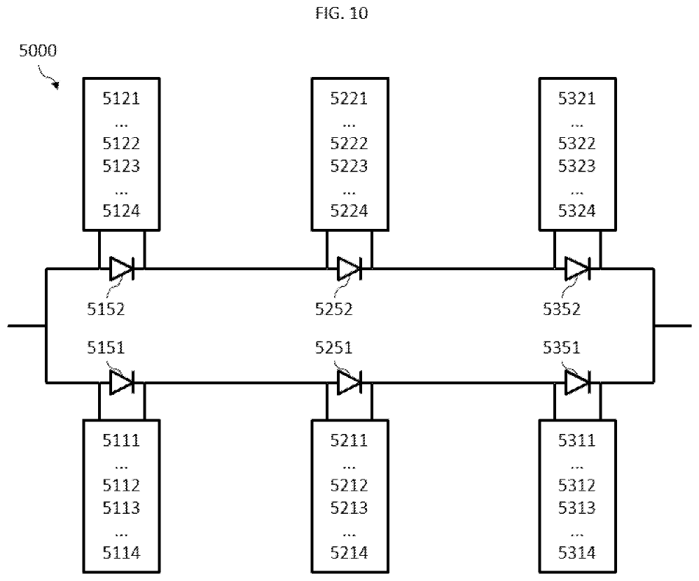

FIG. 10 shows a schematic circuit diagram of the solar cell module shown in FIG. 8.

FIG. 1 shows a first solar cell module 2000 with a plurality of solar cell strings 2121, 2122, 2123, 2124; 2221, 2222, 2223, 2224; 2321, 2322, 2323, 2324; 2111, 2112, 2113, 2114; 2211, 2212, 2213, 2214 and 2311, 2312, 2313, 2314. Ssolar cell string 2121, 2122, 2123, 2124 can also be regarded as the first solar cell string. The first solar cell string comprises a plurality of, in particular at least two solar cells 2121, 2122, 2123 and 2124 connected in series. FIG. 1 shows four solar cells per solar cell string. However, it is also conceivable to provide eight, ten, twelve or, in particular, twenty solar cells per solar cell string. The solar cells of the first solar cell string are arranged in two rows. One row comprises solar cells 2121 and 2122, and the other row comprises solar cells 2123 and 2124. The other solar cell strings of solar cell module 2000 have the same structure, wherein solar cell strings 2111, 2112, 2113, 2114; 2211, 2212, 2213, 2214 and 2311, 2312, 2313, 2314 are respectively arranged mirror-symmetrically to solar cell strings 2121, 2122, 2123, 2124; 2221, 2222, 2223, 2224 and 2321, 2322, 2323, 2324. Accordingly, the solar cell module 2000 has six times twenty solar cells arranged in twenty lines and six rows. It is conceivable to vary the number of lines and thus the number of solar cells per solar cell string. Likewise, more or fewer solar cell strings can be used, so that the number of rows can also differ. Embodiments can also provide that the solar cell strings of the lower half of solar cell module 2000, as shown in FIG. 1, are omitted.

A first bypass element 2151 is connected in parallel to first solar cell string 2121, 2122, 2123, 2124. A second bypass element 2251 is connected in parallel to second solar cell string 2221, 2222, 2223, 2224 in a comparable manner Bypass elements 2151 and 2251 are configured as diodes in the example of a solar cell module 2000 shown in FIG. 1. However, it is also conceivable to use other bypass elements, e.g., active switches, instead of the diodes.

FIG. 2 shows that solar cells 2111, . . . , 2114; 2211, . . . , 2214; 2311, . . . 2314 of the total of six solar cell strings of the solar cell module 2000 are arranged between a front side encapsulation layer 2002 and a rear side encapsulation layer 2003. Front side encapsulation layer 2002 and rear side encapsulation layer 2003 protect solar cells 2111, . . . , 2114; 2211, . . . 2214; 2311, . . . , 2314 from harmful environmental influences, especially moisture. The combination of front side encapsulation layer 2002, solar cells 2111, . . . 2114; 2211, . . . , 2214; 2311, . . . , 2314 and rear side encapsulation layer can also be referred to as a laminate.

An internal electrical connector 2062 is arranged between the front side encapsulation layer 2002 and the rear side encapsulation layer 2003. First solar cell string 2121, 2122, 2123, 2124 and second solar cell string 2221, 2222, 2223, 2224 are connected in series to electrical internal connector 2062. In particular, internal electrical connector 2062 connects solar cells 2124 and 2221 to one another.

First bypass element 2151 and second bypass element 2251 are arranged on the side of the rear side encapsulation layer 2003 facing away from the front side encapsulation layer 2002 and are electrically conductively connected to one another with an external electrical connector 2072 arranged on the side of the rear side encapsulation layer 2003 facing away from the front side encapsulation layer 2002. By providing external electrical connector 2072 and internal electrical connector 2062, the number of feedthroughs 2081, 2082, 2085, 2086 required through rear side encapsulation layer 2003 can be reduced. Four such feedthroughs 2081, 2082, 2085, 2086 are shown in FIG. 2. However, it is also conceivable for two electrical connections to be routed through only a single feedthrough. For example, feedthroughs 2081, 2082 of a single feedthrough could be combined.

The solar cell module 20000 has a junction box 2091 arranged on the side of rear side encapsulation layer 2003 facing away from the front side encapsulation layer 2002, wherein first bypass element 2151 and second bypass element 2251 are arranged in junction box 2091. Furthermore, the solar cell module 2000 has a bypass element 2351 which is connected in parallel to solar cell string 2321, 2322, 2323, 2324. Bypass element 2351 is connected to second bypass element 2251 with a further external electrical connector 2073. Furthermore, solar cell string 2321, 2322, 2323, 2324 is electrically connected to second solar cell string 2221, 2222, 2223, 2224 by means of an electrical internal connector 2063. In this case, an internal electrical connector 2063 is arranged between front side encapsulation layer 2002 and rear side encapsulation layer 2003.

Finally, the solar cell module 2000 has connections 2071 and 2074 with which it can be connected to a power grid. Connections 2071 and 2074 are also provided by means of junction box 2091. To protect the laminate, a front side glass 2001 is arranged on the side of the front side encapsulation layer facing away from the rear side encapsulation layer. Likewise, a rear side glass or a backsheet 2004 can be arranged on the side of rear side encapsulation layer 2003 facing away from front side encapsulation layer 2002 In this case, in particular first bypass element 2151 and/or second bypass element 2251 and/or third bypass element 2351 can be arranged on the side of the rear glass or backsheet 2004 facing away from rear side encapsulation layer 2003.

The solar cell module 2000 further has solar cell string 2111, 2112, 2113, 2114, which can also be referred to as the third solar cell string. Third solar cell string 2111, . . . , 2114 is connected to first solar cell string 2121, . . . 2124 in parallel. In the illustrative example shown in FIG. 1, the parallel connection is realized by internal electrical connectors which are arranged between front side encapsulation layer 2002 and rear side encapsulation layer 2003.

In the embodiment shown in FIG. 1, the solar cells are half-cells. In principle, however, it is also conceivable to use full cells or quarter cells as solar cells for solar cell module 2000 shown. In principle, multi-divided cells can also be used.

FIG. 3 shows another solar cell module 3000. Solar cell module 3000 in turn has a plurality of solar cell strings 3121, 3122, 3123, 3124; 3221, 3222, 3223, 3224; 3321, 3322, 3323, 3324; 3111, 3112, 3113, 3114; 3211, 3212, 3213, 3214; 3311, 3312, 3313, 3314. With regard to the number of solar cells per solar cell string and the spatial arrangement of the solar cells, reference is made to the remarks relating to FIG. 1, which apply analogously.

Solar cell module 3000 also comprises a first bypass element 3151, a second bypass element 3251 and a third bypass element 3351, which are each connected in parallel to solar cell string 3121, . . . 3124, to solar cell string 3221 . . . , 3224 or to solar cell string 3321, . . . 3324. An electrically conductive connection between solar cells 3124 and 3221 and 3224 and 3321 is established via electrical internal connectors 3062 and 3063, which are each arranged between the front side encapsulation layer 3002 and the rear side encapsulation layer 3003. Feedthroughs 3081 and 3085 allow electrical connectors to be routed through rear side encapsulation layer 3003. In contrast to the example shown in FIG. 2, one feedthrough is provided for two lines in each case. In principle, however, a configuration such as that shown in FIGS. 1/2 would also be conceivable.

The example of a solar cell module 3000 shown in FIGS. 3 and 4 has two junction boxes 3091, 3092. Bypass elements 3151, 3251, 3351 are arranged in one of the two junction boxes 3091, 3092. Connections 3071 and 3079 of the solar cell module 3000 are provided by different junction boxes 3091, 3092. External electrical connectors 3071, 3072, 3073, 3074 are provided for connecting bypass elements 3151, 3251, 3351 to one another and to the solar cell strings. External electrical connectors 3071, 3072, 3073, 3074 are arranged on a side of rear side encapsulation layer 3003 facing away from front side encapsulation layer 3002.

Providing two junction boxes 3091, 3092 can result in a smaller area being covered by opaque materials on the rear side of solar cell module 3000. Solar cell module 3000 can therefore be particularly suitable for illumination from both sides.

Another solar cell module 4000 is shown in FIGS. 5 and 6. Regarding solar cell strings 4121, 4122, 4123, 4124; 4221, 4222, 4223, 4224; 4321, 4322, 4323, 4324; 4111, 4112, 4113, 4114; 4211, 4212, 4213, 4214 and 4311, 4312, 4313, 4314 and the spatial arrangement of the corresponding solar cells, reference is made to the remarks relating to solar cell module 1000. Solar cells 4124 and 4221 as well as 4224 and 4321 are connected in series by means of internal electrical connectors 4062,4063.

A first bypass element 4152 is connected in parallel to first solar cell string 4121, . . . 4124 and, in a comparable manner, a second bypass element 4252 is connected in parallel to second solar cell string 4221, . . . , 4224. Furthermore, a third bypass element 4151 is connected in parallel to third solar cell string 4111, . . . , 4114. Further bypass elements 4251, 4351 and 4352 are connected in parallel to the further solar cell strings in a corresponding manner Bypass elements 4151, 4251 and 4152 are arranged in a first junction box 4091 and bypass elements 4351, 4252, 4352 are provided in a second junction box 4092. Furthermore, a first connection 4071 of solar cell module 4000 is provided by first junction box 4091 and a second connection 4079 of solar cell module 4000 is provided by second junction box 4092.

Junction boxes 4091, 4092 each have three bypass elements 4151, 4251, 4152 or 4351, 4252, 4352. This can help to distribute the waste heat generated by bypass elements 4151, 4251, 4152, 4351, 4252, 4352 to both junction boxes 4091, 4092. The thermal load on respective junction box 4091, 4092 can consequently be reduced.

External connectors 4072, 4073, 4074 and 4075 are provided for the connection between bypass elements 4151, 4251, 4152, 4351, 4252, 4352 and to the solar cell strings. In particular, external connectors 4073, 4074, which connect two junction boxes 4091, 4092, can be equipped as flexible cables.

FIG. 6 shows two feedthroughs 4081, 4082 or 4085, 4086 in rear side encapsulation layer 4003, which allow electrical connectors to be routed to the outside. Only one corresponding feedthrough is provided in each case in rear side film or glass 4004. This can allow better electrical insulation of the solar cells or internal electrical connectors and reduce the effort involved in processing the rear side film or the rear side glass. A corresponding reduction in the number of feedthroughs in the rear side film or the rear side glass in relation to the number of feedthroughs in the rear side encapsulation layer can also be provided for differently designed solar cell modules, in particular solar cell modules that are constructed similarly to solar cell modules 2000, 3000, 5000.

FIG. 7 shows a schematic circuit diagram of solar cell module 4000.

A solar cell module 5000 is also shown in FIGS. 8 to 10, wherein a schematic circuit diagram of solar cell module 5000 is shown in FIG. 10.

Three solar cell strings 5121, . . . , 5124; 5221, . . . , 5224; 5321, . . . 5324 and 5111, . . . , 5114; 5211, . . . , 5214; 5311, . . . 5314 are connected in series and the solar cell strings connected in series are then connected in parallel. Each of solar cell strings 5121, . . . , 5124; 5221, . . . , 5224; 5321, . . . , 5324; 5111, . . . , 5114; 5211, . . . 5214; 5311, . . . 5314 is assigned a bypass element 5152, 5252, 5352, 5151, 5251, 5351 in each case.

With regard to the arrangement of the individual solar cell strings shown in FIG. 8, reference is made to the remarks relating to solar cell module 2000 shown in FIG. 1. Solar cell module 5000 has internal electrical connectors 5062, 5063, 5066, 5067, which connect solar cells 5114 and 5211, 5214 and 5311, 5124 and 5221, 5224 and 5321 to one another in each case between front side encapsulation layer 5002 and rear side encapsulation layer 5003. Furthermore, external electrical connectors 5072, 5073, 5074 and 5075 are provided, which connect bypass elements 5151, 5152, 5251, 5351, 5252, 5352 outside the laminate of solar cell module 5000 to one another.

Bypass elements 5151, 5152, 5251, 5351, 5252, 5352 are distributed over two junction boxes 5091, 5092. The use of two junction boxes 5901, 5092 can result in the solar cell module 5000 being able to react more flexibly to mechanical loads. Consequently, solar cell module 5000 can be exposed to a lower risk of damage than known solar cell modules. Connections 5071, 5079 of solar cell module 5000 are in turn distributed over the two junction boxes 5091 and 5092.

Furthermore, solar cell module 5000 has a rear side glass 5004 and a front side 85008 in rear side glass 5004 and rear side encapsulation layer 5003 four feedthroughs 5081, 5082, 5085 and 5086 are provided, which allow elements outside the laminate to be electrically connected to elements inside the laminate.

In summary, a plurality of variants of a solar cell module are proposed. Variants of the solar cell module are characterized by a small number of feedthroughs through a rear side encapsulation layer, which means that the solar cell modules can be made more resistant to harsh environmental influences. In addition, the production cost of the solar cell modules described can be reduced compared to known solar cell modules.

1-13. (canceled)

14. A solar cell module, comprising:
a first solar cell string comprising at least two solar cells connected in series and arranged in two rows;
a first bypass element connected in parallel to the first solar cell string;
a second solar cell string having at least two solar cells connected in series and arranged in two rows;
a second bypass element connected in parallel to the second solar cell string;
a front side encapsulation layer and a rear side encapsulation layer, wherein the solar cells of the first solar cell string and the second solar cell string are arranged between the front side encapsulation layer and the rear side encapsulation layer;
an internal electrical connector arranged between the front side encapsulation layer and the rear side encapsulation layer, and to which the first solar cell string and the second solar cell string are connected in series;
wherein the first bypass element and the second bypass element are arranged on the side of the rear side encapsulation layer facing away from the front side encapsulation layer;
wherein the first bypass element and the second bypass element are electrically conductively connected to one another with an external electrical connector arranged on the side of the rear side encapsulation layer facing away from the front side encapsulation layer; and
wherein a number of feedthroughs through the rear side encapsulation layer is less than the number of bypass elements of the solar cell module.

15. The solar cell module according to claim 14,
wherein the solar cell module has a junction box arranged on the side of the rear side encapsulation layer facing away from the front side encapsulation layer, and
wherein the first bypass element and the second bypass element are arranged in the junction box.

16. The solar cell module according to claim 14, further comprising:
a third solar cell string having at least two solar cells connected in series and arranged in two rows;
wherein the third solar cell string is arranged mirror-symmetrically to the first solar cell string.

17. The solar cell module according to claim 16,
wherein the third solar cell string is connected in parallel to the first solar cell string.

18. The solar cell module according to claim 16,
wherein the third solar cell string and the first solar cell string are insulated between the front side encapsulation layer and the rear side encapsulation layer.

19. The solar cell module according to claim 16, further comprising:
a third bypass element connected in parallel to the third solar cell string.

20. The solar cell module according to claim 14,
wherein the solar cells are half cells or multi-divided cells.

21. The solar cell module according to claim 14,
wherein a front side glass is arranged on a side of the front side encapsulation layer facing away from the rear side encapsulation layer.

22. The solar cell module according to claim 19,
wherein a rear side glass or a backsheet is arranged on a side of the rear side encapsulation layer facing away from the front side encapsulation layer; and
wherein one of the first bypass element, the second bypass element, and the third bypass element are arranged on a side of the rear side glass or rear reinforcement facing away from the rear side encapsulation layer.

23. The solar cell module according to claim 14,
wherein the solar cell module is configured to generate electricity both when light passes through the front side encapsulation layer and when light passes through the rear side encapsulation layer.

24. The solar cell module according to claim 19,
wherein at least one of the first bypass element, the second bypass element, and the third bypass element each comprise a diode or an active switch.

25. A solar cell module, comprising:
a first solar cell string having has at least two solar cells connected in series and arranged in two rows,
a first bypass element connected in parallel to the first solar cell string;
a second solar cell string having at least two solar cells connected in series and arranged in two rows;
a second bypass element connected in parallel to the second solar cell string;
with a front side encapsulation layer and a rear side encapsulation layer, wherein the solar cells of the first solar cell string and the second solar cell string are arranged between the front side encapsulation layer and the rear side encapsulation layer; and
an internal electrical connector arranged between the front side encapsulation layer and the rear side encapsulation layer, and to which the first solar cell string and the second solar cell string are connected in series;
wherein the first bypass element and the second bypass element are arranged on a side of the rear side encapsulation layer facing away from the front side encapsulation layer;
wherein the first bypass element and the second bypass element are electrically conductively connected to one another with an external electrical connector arranged on the side of the rear side encapsulation layer facing away from the front side encapsulation layer; and
wherein a number of feedthroughs through a rear side glass or a backsheet is less than a number of feedthroughs through the rear side encapsulation layer.

26. The solar cell module according to claim 25,
wherein the solar cell module has a junction box arranged on the side of the rear side encapsulation layer facing away from the front side encapsulation layer, and
wherein the first bypass element and the second bypass element are arranged in the junction box.

27. The solar cell module according to claim 25, further comprising:
a third solar cell string having at least two solar cells connected in series and arranged in two rows;
wherein the third solar cell string is arranged mirror-symmetrically to the first solar cell string.

28. The solar cell module according to claim 27,
wherein the third solar cell string is connected in parallel to the first solar cell string.

29. The solar cell module according to claim 27, wherein the third solar cell string and the first solar cell string are insulated between the front side encapsulation layer and the rear side encapsulation layer.

30. The solar cell module according to claim 27, further comprising:
a third bypass element connected in parallel to the third solar cell string.

31. The solar cell module according to claim 25,
wherein the solar cells are half cells or multi-divided cells.

32. The solar cell module according to claim 25,
wherein a front side glass is arranged on a side of the front side encapsulation layer facing away from the rear side encapsulation layer.

33. The solar cell module according to claim 30,
wherein a rear side glass or a backsheet is arranged on a side of the rear side encapsulation layer facing away from the front side encapsulation layer; and
wherein one of the first bypass element, the second bypass element, and the third bypass element are arranged on a side of the rear side glass or rear reinforcement facing away from the rear side encapsulation layer.

34. The solar cell module according to claim 25,
wherein the solar cell module is configured to generate electricity both when light passes through the front side encapsulation layer and when light passes through the rear side encapsulation layer.

35. The solar cell module according to claim 30,
wherein at least one of the first bypass element, the second bypass element, and the third bypass element comprises a diode or an active switch.
